(19) United States
(12) Patent Application Publication
(10) Pub. No.: US 2021/0288197 A1
(43) Pub. Date: Sep. 16, 2021

(54) PHOTOVOLTAIC MODULE

(71) Applicants: Hillel ROSENFELD, Netanya (IL); Juan Carlos ALONSO GUTIERREZ, Hong Kong (CN)

(72) Inventors: Hillel ROSENFELD, Netanya (IL); Juan Carlos ALONSO GUTIERREZ, Hong Kong (CN)

(21) Appl. No.: 16/324,941

(22) PCT Filed: Aug. 16, 2017
(86) PCT No.: PCT/IL2017/050901

§ 371 Date: Feb. 12, 2019

(30) Foreign Application Priority Data
Aug. 30, 2016 (IL) 247556

(51) Int. Cl. H01L 31/0465; H02S 20/10

(52) U.S. Cl. CPC H01L 31/0465; H02S 20/10

(57) ABSTRACT

A photovoltaic module, including: a plurality of photovoltaic areas deployed on a flat flexible panel; and a plurality of areas being empty, while the flexible panel is flat, each of the empty areas being disposed between adjacent photovoltaic areas, thereby folding of the adjacent photovoltaic areas one in relation to the other, draws ends of the adjacent photovoltaic areas one towards the other, turns the flat flexible panel to be domed, thereby the photovoltaic module is attachable to a domed panel.

### TECHNICAL FIELD

The invention relates to the field of photovoltaic modules. More particularly, the invention relates to curved photovoltaic modules.

### BACKGROUND

FIG. 1 depicts a prior art curved photovoltaic module.

A prior art photovoltaic module 26 includes a plurality of photovoltaic cells 60A, 60B, etc. deployed on a flat flexible panel 24. Thus, panel 24 may be neatly curved along axis 22.

FIG. 2 depicts an attempt to curve the prior art photovoltaic module of FIG. 1 along two axes.

However, an attempt to curve flat flexible panel 24 as well along axis 28, for curving it multi-dimensionally, produces protrusions, such as protrusion 50, and undesirable folds 30, which might be breakable.

FIG. 3 depicts an attempt to attach the curved prior art photovoltaic module of FIG. 2 to a domed panel.

Protrusion 50 does not allow neat attachment of prior art photovoltaic module 26 to a domed panel 32.

### SUMMARY

A photovoltaic module, including:
a plurality of photovoltaic areas; and
a plurality of areas being empty, while the flexible panel is flat.

### BRIEF DESCRIPTION OF THE DRAWINGS

FIG. 1 depicts a prior art curved photovoltaic module.

FIG. 2 depicts an attempt to curve the prior art photovoltaic module of FIG. 1 along two axes.

FIG. 3 depicts an attempt to attach the curved prior art photovoltaic module of FIG. 2 to a domed panel.

FIG. 4 depicts a photovoltaic module according to one embodiment of the invention, and the operation of attaching it to the domed panel of FIG. 3.

FIG. 5 depicts the photovoltaic module of FIG. 4, upon attaching it to the domed panel of FIG. 4.

FIG. 6 depicts the electric circuit of the photovoltaic module of FIG. 1.

FIG. 7 discloses the solution to the problem of the cutting.

### DETAILED DESCRIPTION

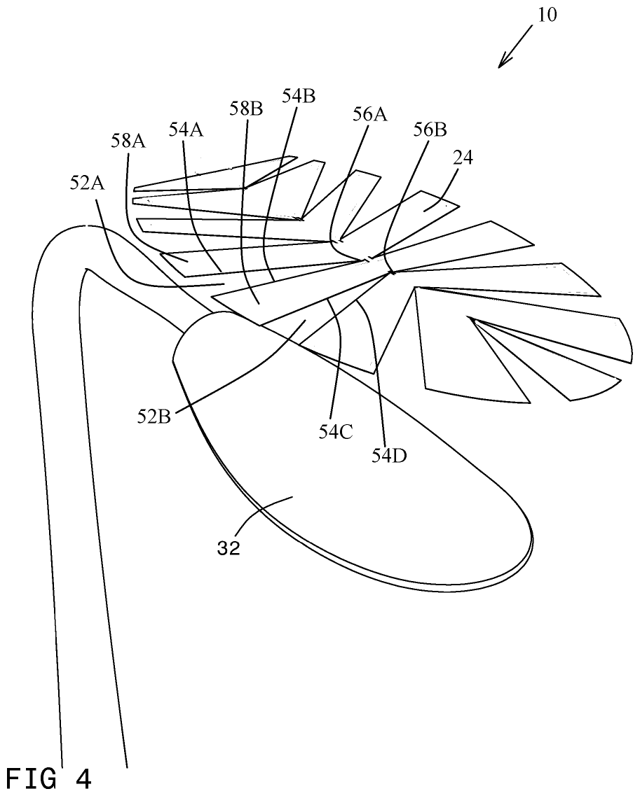

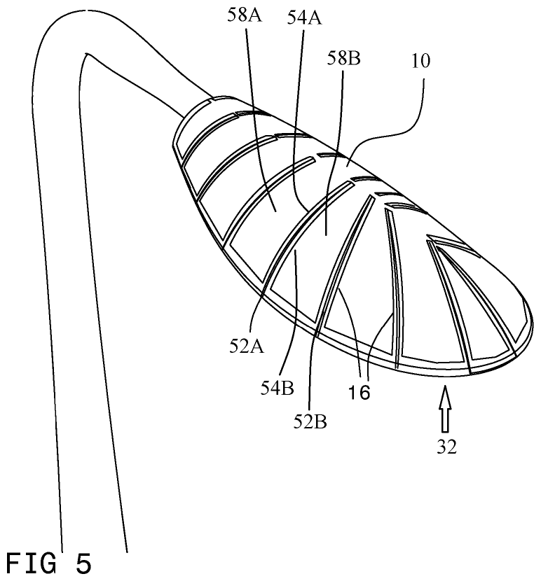

FIG. 4 depicts a photovoltaic module according to one embodiment of the invention, and the operation of attaching it to the domed panel of FIG. 3.

A photovoltaic module 10 according to one embodiment of the invention, includes flat flexible panel 24, having a plurality of empty areas 52A, 52B, etc. Empty area 52A is disposed between photovoltaic areas 58A and 58B. Empty area 52A includes line cuts 54A and 54B both extending from a point 56A; empty area 52B includes line cuts 54C and 54D both extending from a point 56B.

FIG. 5 depicts the photovoltaic module of FIG. 4, upon attaching it to the domed panel of FIG. 4.

Pressing of photovoltaic areas 58A and 58B onto domed panel 32, for attaching photovoltaic module 10 to domed panel 32, draws cut lines 54A and 54B one towards the other and as well photovoltaic areas 58A and 58B one towards the other.

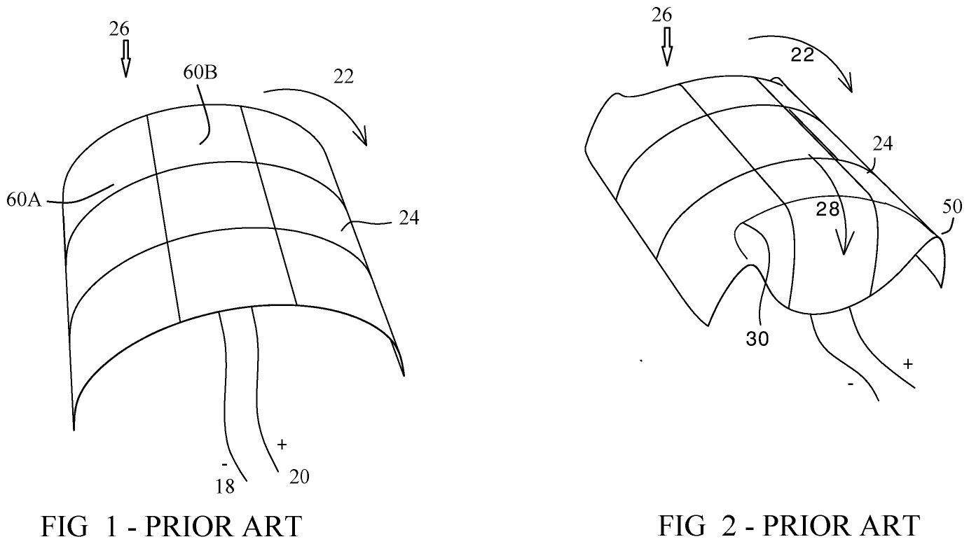

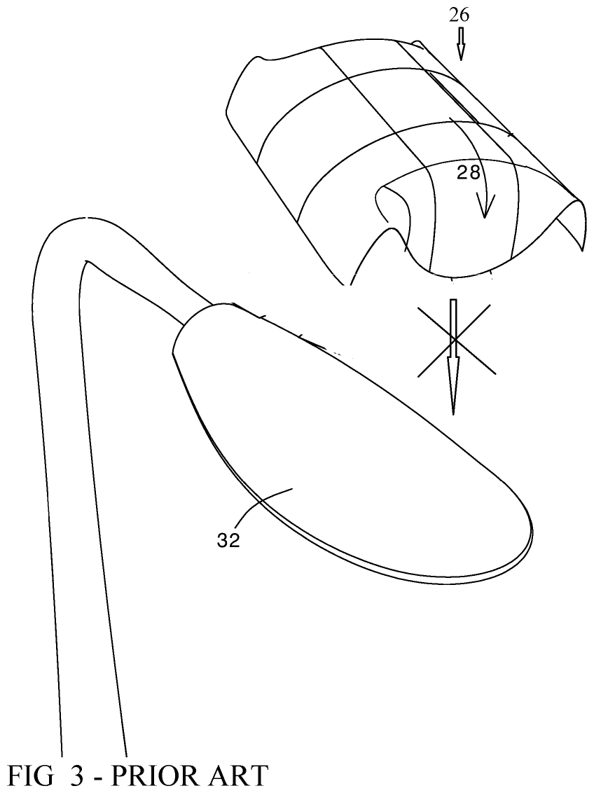

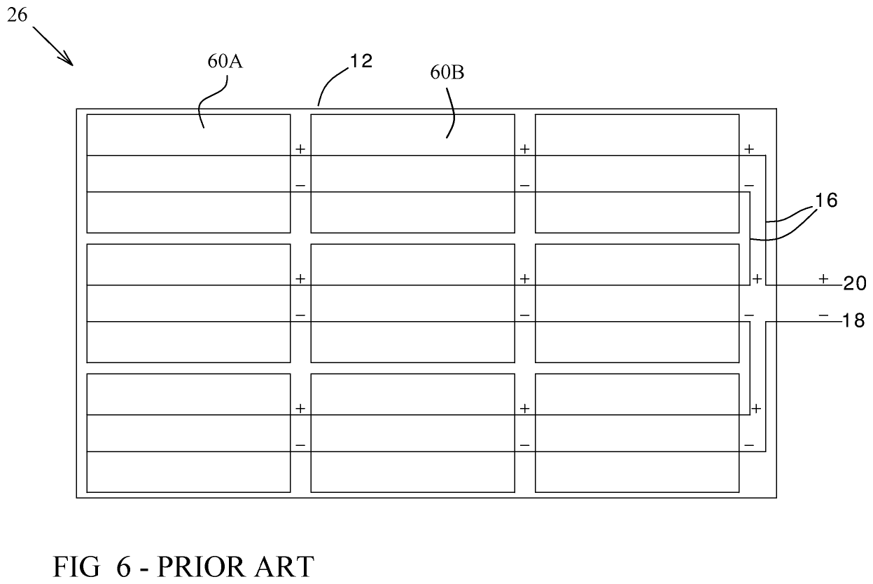

FIG. 6 depicts the electric circuit of the photovoltaic module of FIG. 1.

However, the cutting of FIG. 4 cuts each of solar cells 60A, 60B, etc., and further cuts wires 16 connecting between the photovoltaic cells 60A, 60B, etc.

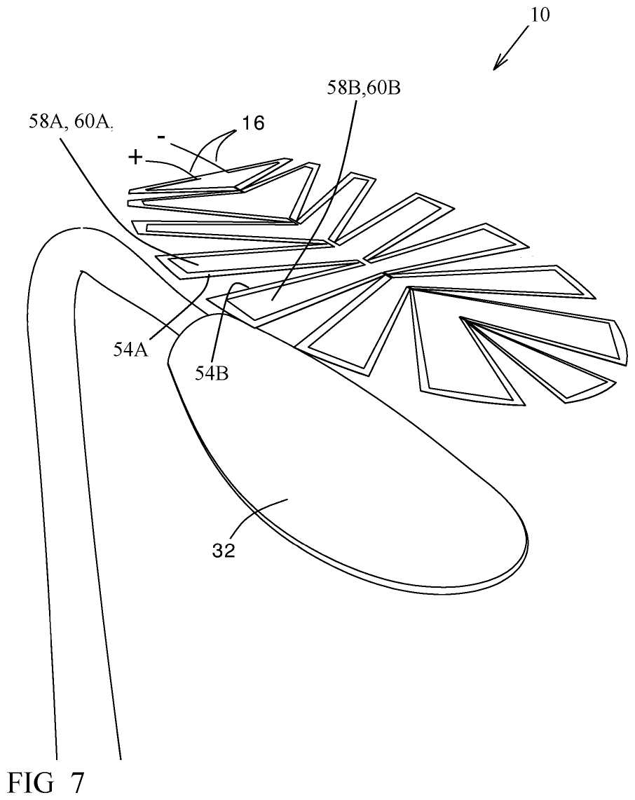

FIG. 7 discloses the solution to the problem of the cutting.

The solution is that photovoltaic cell 60A occupies panel 58A, photovoltaic cell 60B occupies panel 58B, etc.

Further wires 16 between the photovoltaic cells 60A, 60B, etc., does not go through cuts 54A and 54B, but rather along and near the cuts, for surrounding them.
Numeral 10 denotes the photovoltaic module, according to one embodiment of the invention;
numeral 12 denotes a frame;
numeral 16 denotes wiring between the photovoltaic cells, and electrodes;
numeral 18 denotes the minus electrode of the photovoltaic module;
numeral 20 denotes the plus electrode of the photovoltaic module;
numeral 30 denotes an undesirable fold;
numeral 22 denotes an axis;
numeral 24 denotes the panel including the photovoltaic cells;
numeral 26 denotes a prior art photovoltaic module;
numeral 28 denotes an axis;
numeral 32 denotes a domed panel, onto which the photovoltaic module is to be attached; for example domed panel 32 may be the roof of a lamp, to be powered by the photovoltaic module;
numeral 50 denotes a protrusion;
numerals 52A and 52B each denotes an area, being cut from the panel;
numerals 54A, 54B, 54C and 54D each denotes a cut on the area;
numerals 56A and 56B each denotes a meeting of two cut lines; and
numerals 58A and 58B each denotes an area remaining from the cutting; and
numerals 60A and 60B denote photovoltaic cells.

The reference numbers in the claims should not be interpreted as limiting the claims.

What is claimed is:

1. A photovoltaic module (10), comprising:
a plurality of photovoltaic areas (54A, 54B) deployed on a flat flexible panel (24); and
a plurality of areas (52A, 52B) being empty, while said flexible panel (24) is flat, each of said empty areas (52A, 52B) being disposed between adjacent photovoltaic areas (54A, 54B),
thereby folding of said adjacent photovoltaic areas (54A, 54B) one in relation to the other, draws ends (54A, 54B) of said adjacent photovoltaic areas (54A, 54B) one towards the other, turns said flat flexible panel (24) to be domed,
thereby said photovoltaic module (10) is attachable to a domed panel (32).

2. A photovoltaic module (10) according to claim 1, further comprising:
wiring (16) extending between said adjacent photovoltaic areas (54A, 54B), without crossing through said empty areas (52A, 52B) disposed between said adjacent photovoltaic areas (54A, 54B).

3. A photovoltaic module (10) according to claim 1, wherein each of said empty areas (52A) disposed between adjacent photovoltaic areas (54A, 54B), is shaped to form a point connection (56A), for connecting said adjacent photovoltaic areas (54A, 54B) one to the other.

4. A photovoltaic module (10) according to claim 1, for powering an electric appliance comprising a domed panel roof.
